(19) United States
(12) Patent Application Publication
(10) Pub. No.: US 2022/0004907 A1
(43) Pub. Date: Jan. 6, 2022

(54) WORKSPACE OCCUPANCY ESTIMATION

(71) Applicant: SIGNIFY HOLDING B.V., EINDHOVEN (NL)

(72) Inventors: Tamir HEGAZY, WINCHESTER, MA (US); Rohit KUMAR, HACKENSACK, NJ (US); Mathan Kumar GOPALSAMY, MEDFORD, MA (US); Liu ANQING, CAMBRIDGE, MA (US)

(21) Appl. No.: 16/613,984

(22) PCT Filed: May 8, 2018
(86) PCT No.: PCT/EP2018/061855

§ 371 Date: Nov. 15, 2019

Related U.S. Application Data
(60) Provisional application No. 62/506,140, filed on May 15, 2017.

(30) Foreign Application Priority Data
May 29, 2017 (EP) 17173165.6

(51) Int. Cl. G06N 7/00; G06N 20/20; G06Q 10/06; G06F 30/13

(52) U.S. Cl. CPC G06N 7/005; G06N 20/20; G06F 30/13; G06Q 10/0637; G06Q 10/0633

(57) ABSTRACT

Techniques are described herein for workspace occupancy estimation using presence sensor data and a predictive model. In various embodiments, spatial distributions of workspaces (340) and presence sensors (342) may be identified (402) in an open environment and used to generate (406) a surrogate model. The surrogate model may indicate which workspaces in the open environment are within sensor range of each presence sensor in the open environment. A plurality of simulated occupancy patterns may be applied across the surrogate model to generate a corresponding plurality of triggered sensor patterns. Based on the applying, a predictive model may be generated (410) for estimating occupancy among the plurality of workspaces in the open environment based on triggered sensor patterns. A real life triggered sensor pattern may then be applied (414) across the predictive model to estimate occupancy among the plurality of workspaces in the environment.

### TECHNICAL FIELD

The present disclosure is directed generally to occupancy estimation. More particularly, various methods and apparatus disclosed herein relate to workspace occupancy estimation using presence sensor data and a predictive model.

### BACKGROUND

Real estate (particularly indoor real estate) is a significant cost for businesses and other entities. Real estate planning tends to rely on knowledge of likely occupancy in a given environment, which enables effective initial deployment of real estate assets, as well as re-deployment of unneeded and/or under-utilized real estate assets. Other techniques and systems for occupancy estimation tend to rely on relatively complex and/or costly equipment such as cameras and thermopiles. Less complex and/or more cost-effective sensors such as passive infrared (“PIR”) sensors have had less success in occupancy estimation, especially in environments having relatively high occupancy rates, largely due to their typically binary output. Thus, there is a need in the art to leverage relatively simple and/or low-cost presence sensors, such as PIR sensors commonly integrated into lighting infrastructure to facilitate energy savings, to accurately and reliable estimate occupancy, especially at predefined workspaces such as desks.

### SUMMARY

The present disclosure is directed to inventive methods and apparatus for workspace occupancy estimation using presence sensor data and a predictive model. For example, in various embodiments, a spatial distribution or map of workspaces (e.g., desks, tabletops, art stations, computer terminals, exercise stations in a gym, etc.) in an environment such as an open floorplan (which are common in commercial enterprises such as offices, gyms, museums, etc.) may be determined, e.g., from information provided by personnel charged with furnishing an environment, a floor plan, etc. Similarly, a spatial distribution or map of presence sensors in the environment, e.g., relative to the workspaces, may also be determined. A so-called “surrogate” model may then be generated that indicates or conveys, e.g., mathematically, which workspaces are within sensing range of which presence sensors.

Supervised machine learning (i.e., training a model using labeled training examples) is an effective approach for detecting occupancy patterns. However, obtaining labeled sensor data generated from real life sensors may be challenging. According, in some embodiments, a number of hypothetical occupancy patterns may then be simulated, e.g., using Monte Carlo analysis or other techniques, to determine responsive triggered sensor statistics, patterns, etc. In effect, these hypothetical occupancy patterns act as “synthesized” training examples for training a supervised learning model. The relationship(s) between the hypothetical occupancy patterns and the responsive triggered sensor statistics may be analyzed, e.g., using regression analysis, to generate a predictive model that estimates occupancy among the workspaces based on real-life presence sensor signals. This real life sensor data may then be applied across this predictive model to estimate, for instance, workspace occupancy. For example, in a space of fifty desks in which thirty are occupied, the predictive model may estimate, based on sensor input, that thirty of those desks are occupied, and twenty are not. This is slightly different than raw headcount, which may simply calculate how many people are in the area, irrespective of desk occupancy.

Generally, in one aspect, a method may include identifying a spatial distribution of workspaces in the open environment; identifying a spatial distribution of presence sensors in the open environment; generating a surrogate model based on the spatial distribution of workspaces and the spatial distribution of presence sensors, wherein the surrogate model indicates which workspaces in the open environment are within sensor range of each sensor in the open environment; applying a plurality of simulated occupancy patterns across the surrogate model to generate a corresponding plurality of triggered sensor patterns, wherein each simulated occupancy pattern simulates a particular occupancy among the plurality of workspaces in the open environment; generating, based on the applying, a predictive model for estimating occupancy among the plurality of workspaces in the open environment, wherein the estimating is based on triggered sensor patterns; determining, based on signals from one or more of the presence sensors in the open environment, a given triggered sensor pattern; and applying the given triggered sensor pattern across the predictive model to estimate occupancy among the plurality of workspaces in the environment.

In various embodiments, the predictive model may be a regression model. In various versions, the regression model may be an exponential regression model. In various embodiments, applying the plurality of simulated occupancy patterns may include performing a Monte Carlo simulation. In various versions, a feature extracted during the Monte Carlo simulation may be a number of presence sensors triggered given a particular simulated occupancy pattern.

In various embodiments, each workspace may take the form of a desk. In various embodiments, at least some of the plurality of presence sensors may include passive infrared sensors. In various embodiments, the surrogate model may include a two-dimensional binary adjacency matrix A such that each element a_{i,j} of A indicates whether a workspace i falls within a sensing range of presence sensor j. Systems and non-transitory computer-readable media for performing the above-described method are also disclosed herein.

The term “controller” is used herein generally to describe various apparatus relating to the operation of one or more components (e.g., light sources) described herein. A controller can be implemented in numerous ways (e.g., such as with dedicated hardware) to perform various functions discussed herein. A “processor” is one example of a controller which employs one or more microprocessors that may be programmed using software (e.g., microcode) to perform various functions discussed herein. A controller may be implemented with or without employing a processor, and also may be implemented as a combination of dedicated hardware to perform some functions and a processor (e.g., one or more programmed microprocessors and associated circuitry) to perform other functions. Examples of controller components that may be employed in various embodiments of the present disclosure include, but are not limited to, conventional microprocessors, application specific integrated circuits (ASICs), and field-programmable gate arrays (FPGAs).

In various implementations, a processor or controller may be associated with one or more storage media (generically referred to herein as “memory,” e.g., volatile and non-volatile computer memory such as RAM, PROM, EPROM, and EEPROM, floppy disks, compact disks, optical disks, magnetic tape, etc.). In some implementations, the storage media may be encoded with one or more programs that, when executed on one or more processors and/or controllers, perform at least some of the functions discussed herein. Various storage media may be fixed within a processor or controller or may be transportable, such that the one or more programs stored thereon can be loaded into a processor or controller so as to implement various aspects of the present disclosure discussed herein. The terms “program” or “computer program” are used herein in a generic sense to refer to any type of computer code (e.g., software or microcode) that can be employed to program one or more processors or controllers.

The term “addressable” is used herein to refer to a device (e.g., a light source in general, a luminaire or fixture, a controller or processor associated with one or more light sources or lighting units, other non-lighting related devices, etc.) that is configured to receive information (e.g., data) intended for multiple devices, including itself, and to selectively respond to particular information intended for it. The term “addressable” often is used in connection with a networked environment (or a “network,” discussed further below), in which multiple devices are coupled together via some communications medium or media.

In one network implementation, one or more devices coupled to a network may serve as a controller for one or more other devices coupled to the network (e.g., in a master/slave relationship). In another implementation, a networked environment may include one or more dedicated controllers that are configured to control one or more of the devices coupled to the network. Generally, multiple devices coupled to the network each may have access to data that is present on the communications medium or media; however, a given device may be “addressable” in that it is configured to selectively exchange data with (i.e., receive data from and/or transmit data to) the network, based, for example, on one or more particular identifiers (e.g., “addresses”) assigned to it.

The term “network” as used herein refers to any interconnection of two or more devices (including controllers or processors) that facilitates the transport of information (e.g., for device control, data storage, data exchange, etc.) between any two or more devices and/or among multiple devices coupled to the network. As should be readily appreciated, various implementations of networks suitable for interconnecting multiple devices may include any of a variety of network topologies and employ any of a variety of communication protocols. Additionally, in various networks according to the present disclosure, any one connection between two devices may represent a dedicated connection between the two systems, or alternatively a non-dedicated connection. In addition to carrying information intended for the two devices, such a non-dedicated connection may carry information not necessarily intended for either of the two devices (e.g., an open network connection). Furthermore, it should be readily appreciated that various networks of devices as discussed herein may employ one or more wireless, wire/cable, and/or fiber optic links to facilitate information transport throughout the network.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the disclosure.

FIG. 1 schematically illustrates an example process flow that implement selected aspects of the present disclosure, in accordance with various embodiments.

FIG. 2 depicts an example of exponential regression of simulated occupancies verses responsive numbers of triggered sensors.

FIG. 3 depicts an example open floor plan including spatial distributions of workspaces and presence sensors on which disclosed techniques may be practiced, in accordance with various embodiments.

FIG. 4 depicts an example method for practicing selected aspects of the present disclosure.

FIG. 5 depicts an example computing system architecture.

### DETAILED DESCRIPTION

Real estate (particularly indoor real estate) is a significant cost for businesses and other entities. Real estate planning tend to rely on knowledge of likely occupancy in a given environment, which enables effective initial deployment of real estate assets, as well as re-deployment of unneeded and/or under-utilized real estate assets. Existing techniques and systems for occupancy estimation tend to rely on relatively complex and/or costly equipment such as cameras and thermopiles. Thus, there is a need in the art to leverage relatively simple and/or low-cost presence sensors to accurately and reliable estimate occupancy, especially across predefined workspaces such as desks. In view of the foregoing, various embodiments and implementations of the present disclosure are directed to workspace occupancy estimation using presence sensor data and a predictive model.

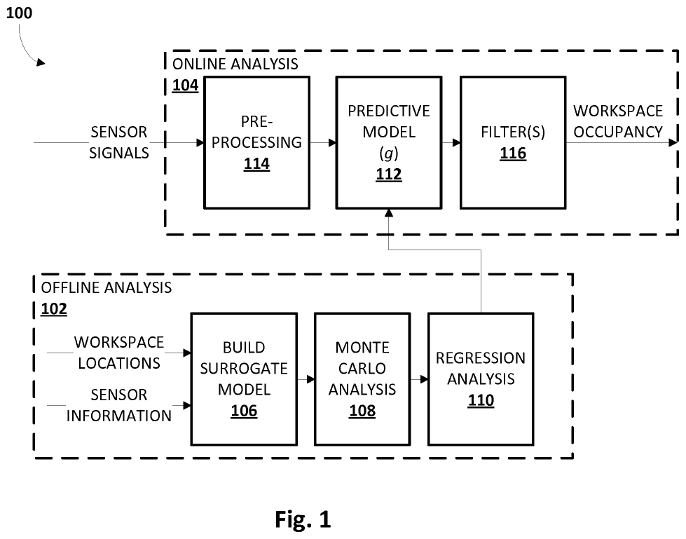

Referring to FIG. 1, an example process flow 100 is depicted that incorporates various aspects of the present disclosure. Workflow 100 includes an offline analysis component 102 and an online analysis component 104. Various components depicted in FIG. 1 may be implemented using any combination of hardware and software. In some embodiments, the components of FIG. 1 may be implemented on multiple computing systems connected via one or more networks (not depicted).

Relatively low-complexity sensors such as PIR sensors and light sensors are often already deployed in environments, e.g., by way of lighting infrastructure. For example, one or more lighting units and/or luminaires may be equipped with one or more integral presence sensors. Additionally or alternatively, other presence sensors may be deployed as standalone components of the lighting infrastructure. In either case, a primary purpose of the sensors may be localized occupancy detection (e.g., someone is present or not present in a particular space) and ambient light detection (e.g., detecting sunlight levels) that are used to determine light output. If an area is unoccupied and/or already sufficiently illuminated by ambient (e.g., natural) light, then one or more light sources or luminaires may be operated to produce less light output than if the area were occupied and/or not sufficiently illuminated by ambient light. However, these sensors may not be suitable by themselves to determine occupancy patterns, such as workspace occupancy, because their outputs tend to be binary.

In various embodiments, slightly more complex sensors deployed in the environment may detect multiple types of movement. For example, in some embodiments, sensors may detect two types of movement: major and minor. In some embodiments, major movement may be movement associated with walking or other similar activity, and may, for instance, include movement greater than or equal to 0.9 m/s. Minor movement may be movement incidental with working at a workspace (e.g., a desk) and in some cases may include movement less than or equal to 0.9 m/s. In other embodiments, sensors may detect additional levels of movement, such as major motion, medium motion, minor motion, and no motion. In some embodiments, only particular types of movements detected by sensors may be considered. For example, to estimate workspace occupancy (e.g., how many/which workspaces are occupied), in some embodiments, only movements associated with motion incidental to occupancy of a workspace, such as minor movement, may be considered.

In various embodiments, offline analysis component 102 may serve to identify relationships (e.g., mappings) between hypothetical occupancy patterns and hypothetical signals triggered by presence sensors in response to the occupancy patterns. Based on these relationships or mappings, it is then feasible to estimate real life workspace occupancy based on real life signals triggered by presence sensors.

In FIG. 1, offline analysis component 102 includes a build surrogate model process 106, a Monte Carlo analysis component 108, and a regression analysis component 110. Build surrogate model process 106 may receive, as input, a spatial distribution of (e.g., locations of) a plurality of workspaces (e.g., desks, exercise stations, etc.) in an environment such as an open floor plan of a building. Build surrogate model process 106 may also receive, as input, a spatial distribution of (e.g., locations of) a plurality of presence sensors (e.g., PIR, light-based sensors, radar or sonar-based sensors, etc.) in the same environment. For example, a corporate database may include records of workspace locations, sizes, purposes, designated occupants (e.g., specific person, title, etc.). Similarly, the same database or a different database may include records of presence sensor locations, presence sensor types, and presence sensor sensing ranges. Alternatively, this data may be input manually.

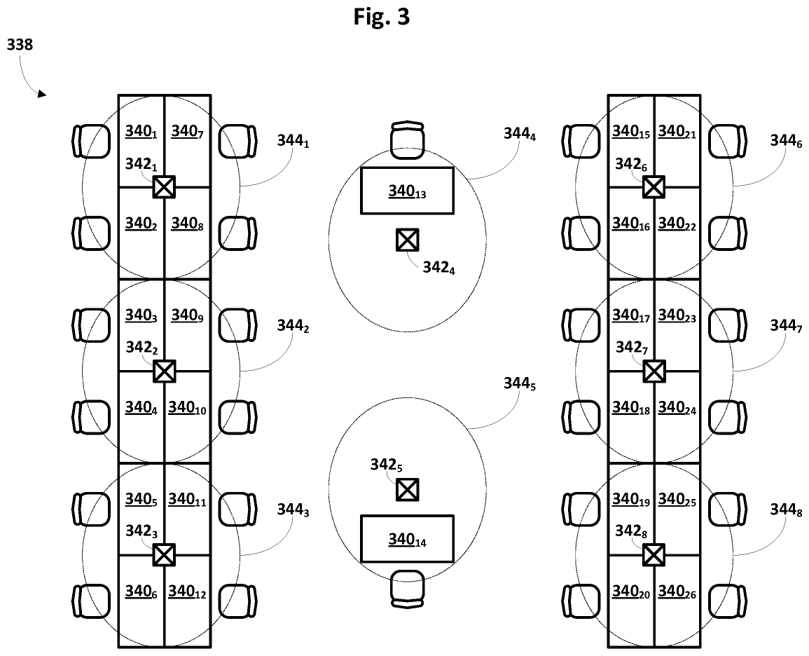

Based on these spatial distributions, build surrogate model process 106 may generate a surrogate model. In various embodiments, the surrogate model may indicate, e.g., using various mathematical techniques (e.g., shorthand such as multi-dimensional matrices) which workspaces in the environment are within sensor range of each sensor in the open environment. One non-limiting example of how a surrogate model may be generated will be described in detail with regard to FIG. 3.

Monte Carlo analysis component 108 may be configured to apply plurality of simulated occupancy patterns across the surrogate model to generate a corresponding plurality of responsive triggered sensor patterns. Each simulated occupancy pattern may simulate a particular occupancy pattern among the plurality of workspaces in the open environment. In some embodiments, the occupancy patterns may particularly simulate minor movement detected at a workspace (e.g., movement incidental with working at a desk), rather than other types of movement, such as major movement (e.g., walking around between workspaces). In some implementations, a number of sensors, Bₛᵤₘ, triggered by each simulated occupancy pattern may be extracted, as a feature (e.g., a regressor) to be used in the Monte Carlo analysis. For example, Bₛᵤₘ may be calculated as follows:

Bₛᵤₘ=Σᵢ₌₁^{N}xᵢ (1)

In various embodiments, xᵢ=1 if the ith sensor is triggered and zero otherwise. N may represent the total number of sensors in the environment, and therefore, Bₛᵤₘ may be an integer between 0 and N.

In various embodiments, Monte Carlo analysis component 108 may perform any number of simulations, nSims, in order to generate nSims responsive triggered sensor patterns. For each simulation j, a random number of subjects in the environment, yⱼ, may be selected. These yⱼ subjects may be allocated to yⱼ randomly-selected workspaces in the environment. Based on the randomly selected workspaces occupied by the subjects, a determination may be made, e.g., by Monte Carlo analysis component 108 based on the surrogate model, of which sensors were triggered. Additionally, for each simulation j, the number of (simulated) triggered sensors, Bₛᵤₘⱼ may be determined. The resulting data generated by Monte Carlo analysis component 108 may be summarized by the following equation:

{y₁,Bₛᵤₘⱼ}ⱼ₌₁^{nSims} (2)

This data may be provided to regression analysis component 110. In various embodiments, regression analysis component 110 may be configured to generate a predictive model (g) 112 for estimating occupancy among the plurality of workspaces in the open environment based on real life triggered sensor patterns. In some cases, predictive model 112 may include a mapping function (g) that maps triggered sensor signals to estimates of workspace occupancy. As suggested by its name, in some embodiments, regression analysis component 110 may implement various regression analysis techniques to generate the predictive model 112. For example, in some embodiments, regression analysis component 110 may apply parametric regression (e.g., an exponential function) Y=g(Bₛᵤₘ), where Y is the number of occupied workstations (e.g., the regressand) and g represents exponential distribution. Thus, the following equation may be applicable:

g(Bₛᵤₘ)=θ₀e^{θ}^{₁}^{×B}^{ₛᵤₘ} (3)

The parameters of g may be estimated using an equation such as the following:

(θ₀,θ₁)=argminₓ_{₀}_{,x}_{₁}Σⱼ₌₁^{nSims}{yⱼ−(x₀e^{x}^{₁}^{×bsum}^{ⱼ})}² (4)

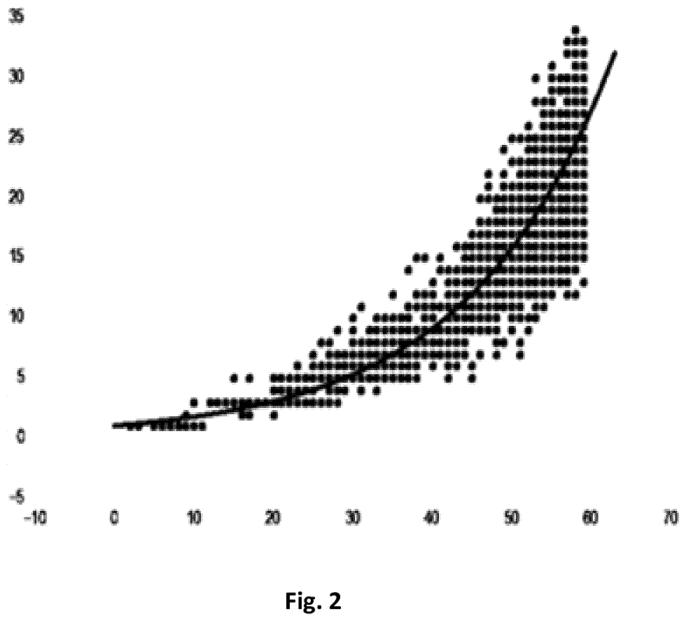

FIG. 2 depicts an example of exponential regression of simulated occupancies versus the responsive numbers of triggered sensors (Bₛᵤₘ). The horizontal axis represents the number of triggered sensors, Bₛᵤₘ. The vertical axis represents simulated occupancies. This, each vertical line of dots essentially represents a histogram of which simulated occupancies resulted from each number of triggered sensors (Bₛᵤₘ). Accordingly, the black line indicates the regression function g (sometimes referred to as a mapping function) that may be computed using the techniques described above.

Referring back to FIG. 1, online analysis component 104 may include the predictive model 112. Online analysis component 104 may receive, e.g., as input for predictive model 112, sensor signals from the plurality of sensors. In some embodiments, the sensor signals received by online analysis component 104 may be preprocessed, e.g., by a pre-processing component 114. In some embodiments, pre-processing component 114 may smooth the sensor data, e.g., using a logical OR operator performed (e.g., over signals representing detected minor movement) over a given time period (e.g., four minutes). If a particular sensor detects movement (e.g., minor movement) at least once within the specified time period, then the sensor is counted as triggered; otherwise it may not be considered triggered in some embodiments.

The preprocessed triggered sensor data may be applied as input across predictive model 112 to generate an estimation of workspace occupancy in the environment.

As described previously, in some embodiments the predictive model may include a regression function, g, that maps input triggered sensor signals (e.g., signals indicative of detected minor movement, which as noted above may be incidental to working at a desk) to occupancy estimates. In some embodiments, an occupancy estimate may include an estimate of the total number work workspaces occupied in the environment. This may facilitate re-deployment of workspaces in the environment, e.g., to optimize use of space. In some embodiments, a median filter may be applied, e.g., via the predictive model, to smooth estimation. In some embodiments, one or more filters 116, such as a median filter, may be applied to the output of the predictive model 112, e.g., to smooth the estimation.

FIG. 3 depicts an example open floor plan environment 338 for which disclosed techniques may be implemented in order to facilitate workspace occupancy detection. In FIG. 3, a plurality of workspaces take the form of a plurality of desks 340₁₋₂₆. Additionally in this example, a plurality of presence sensors 342₁₋₈ are distributed, e.g., as integral components of ceiling-mounted luminaires, in a manner such that they illuminate the desks 340₁₋₂₆. Respective sensing ranges of the sensors 342₁₋₈ are indicated at 344₁₋₈. Thus, for instance, desks 340₁, 340₂, 340₇, and 340₈ are within sensing range of first sensor 342₁. Desks 340₃, 340₄, 340₉, and 340₁₀ are within sensing range of second sensor 342₂. And so on.

In some embodiments, build surrogate model process 106 may use the workspace and sensor distributions to generate a so-called “adjacency” matrix. In some such embodiments, this adjacency matrix may be built in two steps. The first step may be to build a so-called “distance” matrix D in which an element d_{i,j} represents a horizontal distance between desk i and sensor j. The following is an excerpt from an example distance matrix that may be built for the open floor plan environment 338 of FIG. 3.

$$D = ( \begin{matrix}0 & 2 & 4 & … \\ 0 & 1 & 3 & … \\ 1 & 0 & 2 & … \\ 2 & 0 & 1 & … \\ 3 & 1 & 0 & … \\ 4 & 2 & 0 & … \\ 0 & 2 & 4 & … \\ 0 & 1 & 3 & … \\ 1 & 0 & 2 & … \\ 2 & 0 & 1 & … \\ 3 & 1 & 0 & … \\ 4 & 2 & 0 & … \\ ⋮ & ⋮ & ⋮ & ⋮\end{matrix} )$$

This excerpt includes twelve rows that correspond to desks 340₁₋₁₂ and three columns that correspond to sensors 342₁₋₃. For the sakes of brevity and clarity, the ellipses indicate that the matrix may continue to represent the other desks (340₁₃₋₂₆) and sensors (342₄₋₈). The numbers used for distance units are merely selected for illustrative purposes only, and are not meant to represent actual distances (though in real life, actual distances could be used).

Starting at the top of the left-most column that represents sensor 342₁, desks 340₁₋₂ (the top row and second row of D) are zero distance units away, desk 340₃ is one distance unit away, desk 340₄ is two distance units away, desk 340₅ is three distance units away, desk 340₆ is four distance units away, desks 340₇₋₈ are zero units away, desk 340₉ is one unit away, desk 340₁₀ is two distance units away, desk 340₁₁ is three distance units away, and desk 340₁₂ is four distance units away. The second column represents sensor 342₂, the third column represents 342₃, and so on.

In some embodiments, this distance matrix may be used, e.g., by build surrogate model process 106, to generate an adjacency matrix A. For example, the distances in the distance matrix D may be thresholded into binary values such that each element a_{i,j} of adjacency matrix A may indicate whether the desk i falls into a sensing range of the sensor j. Suppose the sensors 342 of FIG. 3 have uniform ranges such that they can detect presence/activity/motion in a range that is less than one (<1) distance unit away. In such a scenario, the distance matrix D above may be used to generate the following adjacency matrix A:

$$A = ( \begin{matrix}1 & 0 & 0 & … \\ 1 & 0 & 0 & … \\ 0 & 1 & 0 & … \\ 0 & 1 & 0 & … \\ 0 & 0 & 1 & … \\ 0 & 0 & 1 & … \\ 1 & 0 & 0 & … \\ 1 & 0 & 0 & … \\ 0 & 1 & 0 & … \\ 0 & 1 & 0 & … \\ 0 & 0 & 1 & … \\ 0 & 0 & 1 & … \\ ⋮ & ⋮ & ⋮ & ⋮\end{matrix} )$$

For each element a_{i,j} in adjacency matrix A, a “1” indicates that a person at desk i would be detected by sensor j. In other words, the number and distribution of ones in adjacency matrix A is a function of sensor coverage and spatial distribution of desks 340. This is just one example of how to compute an adjacency matrix A on which the aforementioned Monte Carlo analysis may be employed. Other techniques are possible. And while desks are depicted in FIG. 3, this is not meant to be limiting. As mentioned above, disclosed techniques may be used to estimate occupancy in other types of workspaces (or more generally, spaces), such as exercise stations, museum exhibits, etc.

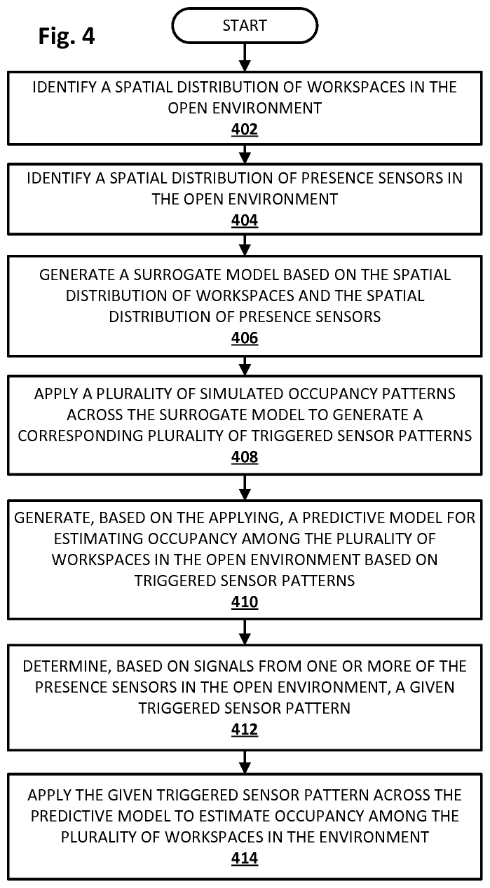

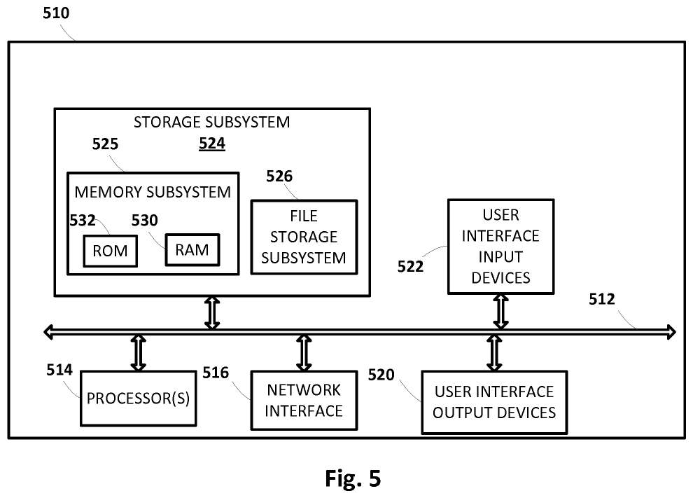

FIG. 4 depicts an example method for practicing selected aspects of the present disclosure, in accordance with various embodiments. For convenience, the operations of the flow chart are described with reference to a system that performs the operations. This system may include various components of various computer systems, including 510 in FIG. 5. Moreover, while operations are shown in a particular order, this is not meant to be limiting. One or more operations may be reordered, omitted or added.

At block 402, the system may identify a spatial distribution of workspaces in a particular environment, such as an indoor open floorplan environment commonly found in many workplaces, gyms, organizations, etc. For example, a floor plan and/or database may include locations of workspaces (e.g., desks) in the area. At block 404, the system may identify a spatial distribution of presence sensors (e.g., PIR sensors, light sensors, etc.) in the environment. For example, lighting infrastructure schematics or plans (or a lighting database) may indicate locations of various sensors which may be integral with lighting units and/or luminaires, and/or which may be standalone sensors.

At block 406, the system may generate a surrogate model based on the spatial distributions of the workspaces and the presence sensors. In various embodiments, the surrogate model may indicate which workspaces in the environment are within sensor range of each sensor in the environment. An example process of building a surrogate model was described above with respect to FIG. 3. In some embodiments, a distance matrix may be generated, and then converted (e.g., using thresholding) into an adjacency matrix.

At block 408, the system may apply a plurality of simulated occupancy patterns across the surrogate model generated at block 406 to generate a corresponding plurality of simulated triggered sensor patterns. Each simulated occupancy pattern may simulate a particular occupancy among the plurality of workspaces in the open environment. As noted above, in some embodiments, the operation(s) of block 408 may include application of Monte Carlo analysis, although other techniques are possible.

At block 410, the system may generate, based on the applying, a predictive model (e.g., g) for estimating occupancy among the plurality of workspaces in the open environment based on triggered sensor patterns. In some embodiments, the predictive model may take the form of a regression function, as was illustrated in FIG. 2. In some embodiments, the predictive model may include a mapping of triggered sensor patterns to workspace occupancy estimations.

At block 412, the system, and in some cases online analysis component 104, may determine, based on signals received in real time from one or more of the presence sensors in the environment, a given triggered sensor pattern. In various embodiments, these sensor signals may be obtained sporadically, continuously, and/or at various time intervals, such as every two to six minutes. At block 414, the system may apply the given triggered sensor pattern across the predictive model to estimate occupancy among the plurality of workspaces in the environment.

The techniques described herein provide a number of advantages. The ability to accurately estimate workspace occupancy with sensors such as occupancy and/or light sensors that are already commonly deployed in work environments provides a significant cost savings relative to existing techniques which rely on more complex sensors (e.g., cameras). Experiments performed using disclosed techniques yielded upwards of 90% accuracy.

The workspace occupancy estimates obtaining using techniques described herein may have numerous applications. As one example, workspace occupancy estimates may be helpful to save energy. Total ventilation rates in buildings vary over time. In many instances the ventilation rates are controlled based on measured carbon dioxide levels, which serve as proxies for indoor concentration of pollutants generated by occupants. However, measured carbon dioxide levels technique tend to be less accurate proxies for workspace occupancy estimation than workspace occupancy estimates produced using disclosed techniques.

Additionally, and as was already mentioned, indoor real estate planning—i.e. addressing space requirements of an organization in a most cost-efficient manner while complying with building codes and other regulations—can be greatly enhanced with workspace occupancy estimates produced using disclosed techniques. As yet another example, operational planners can use workspace occupancy estimates produced using techniques described herein to coordinate maintenance crews, cleaning crews, cafeteria services, and so forth.

FIG. 5 is a block diagram of an example computer system 510. Computer system 510 typically includes at least one processor 514 which communicates with a number of peripheral devices via bus subsystem 512. These peripheral devices may include a storage subsystem 524, including, for example, a memory subsystem 525 and a file storage subsystem 526, user interface output devices 520, user interface input devices 522, and a network interface subsystem 516. The input and output devices allow user interaction with computer system 510. Network interface subsystem 516 provides an interface to outside networks and is coupled to corresponding interface devices in other computer systems.

User interface input devices 522 may include a keyboard, pointing devices such as a mouse, trackball, touchpad, or graphics tablet, a scanner, a touchscreen incorporated into the display, audio input devices such as voice recognition systems, microphones, and/or other types of input devices. In general, use of the term “input device” is intended to include all possible types of devices and ways to input information into computer system 510 or onto a communication network.

User interface output devices 520 may include a display subsystem, a printer, a fax machine, or non-visual displays such as audio output devices. The display subsystem may include a cathode ray tube (CRT), a flat-panel device such as a liquid crystal display (LCD), a projection device, or some other mechanism for creating a visible image. The display subsystem may also provide non-visual display such as via audio output devices. In general, use of the term “output device” is intended to include all possible types of devices and ways to output information from computer system 510 to the user or to another machine or computer system.

Storage subsystem 524 stores programming and data constructs that provide the functionality of some or all of the modules described herein. For example, the storage subsystem 524 may include the logic to perform selected aspects of method 400, and/or to implement one or more aspects of FIG. 1. Memory 525 used in the storage subsystem 524 can include a number of memories including a main random access memory (RAM) 530 for storage of instructions and data during program execution and a read only memory (ROM) 532 in which fixed instructions are stored. A file storage subsystem 526 can provide persistent storage for program and data files, and may include a hard disk drive, a CD-ROM drive, an optical drive, or removable media cartridges. Modules implementing the functionality of certain implementations may be stored by file storage subsystem 526 in the storage subsystem 524, or in other machines accessible by the processor(s) 514.

Bus subsystem 512 provides a mechanism for letting the various components and subsystems of computer system 510 communicate with each other as intended. Although bus subsystem 512 is shown schematically as a single bus, alternative implementations of the bus subsystem may use multiple busses.

Computer system 510 can be of varying types including a workstation, server, computing cluster, blade server, server farm, smart phone, smart watch, smart glasses, set top box, tablet computer, laptop, or any other data processing system or computing device. Due to the ever-changing nature of computers and networks, the description of computer system 510 depicted in FIG. 5 is intended only as a specific example for purposes of illustrating some implementations. Many other configurations of computer system 510 are possible having more or fewer components than the computer system depicted in FIG. 5.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03. It should be understood that certain expressions and reference signs used in the claims pursuant to Rule 6.2(b) of the Patent Cooperation Treaty (“PCT”) do not limit the scope.

1. A computer-implemented method for estimating occupancy among a plurality of workspaces in an open environment, comprising:
identifying, a spatial distribution of the plurality of workspaces in the open environment;
identifying a spatial distribution of a plurality of presence sensors in the open environment;
generating a surrogate model based on the spatial distribution of workspaces and the spatial distribution of presence sensors, wherein the surrogate model indicates which workspaces in the open environment are within sensor range of each presence sensor in the open environment;
applying a plurality of simulated occupancy patterns across the surrogate model to generate a corresponding plurality of triggered sensor patterns, wherein each simulated occupancy pattern simulates a particular occupancy among the plurality of workspaces in the open environment;
generating, based on the applying, a predictive model for estimating occupancy among the plurality of workspaces in the open environment, wherein the estimating is based on triggered sensor patterns;
determining, based on signals from one or more of the presence sensors in the open environment, a given triggered sensor pattern;
applying the given triggered sensor pattern across the predictive model to estimate occupancy among the plurality of workspaces in the environment; and
using the estimated occupancy among the plurality of workspaces to manage energy usage in the environment.

2. The computer-implemented method of claim 1, wherein the predictive model comprises a regression model.

3. The computer-implemented method of claim 2, wherein the regression model is an exponential regression model.

4. The computer-implemented method of claim 1, wherein applying the plurality of simulated occupancy patterns comprises performing a Monte Carlo simulation.

5. The computer-implemented method of claim 4, wherein a feature extracted during the Monte Carlo simulation is a number of presence sensors triggered given a particular simulated occupancy pattern.

6. The computer-implemented method of claim 1, wherein each workspace comprises a desk.

7. The computer-implemented method of claim 1, wherein at least some of the presence sensors comprise passive infrared sensors.

8. The computer-implemented method of claim 1, wherein the surrogate model comprises a two-dimensional binary adjacency matrix A such that each element a_{i,j} of A indicates whether a workspace i falls within a sensing range of presence sensor j.

9. A system comprising logic configured to:
identify a spatial distribution of a plurality of workspaces in an open environment;
identify a spatial distribution of a plurality of presence sensors in the open environment;
generate a surrogate model based on the spatial distribution of workspaces and the spatial distribution of presence sensors, wherein the surrogate model indicates which workspaces in the open environment are within sensor range of each presence sensor in the open environment;
apply a plurality of simulated occupancy patterns across the surrogate model to generate a corresponding plurality of triggered sensor patterns, wherein each simulated occupancy pattern simulates a particular occupancy among the plurality of workspaces in the open environment;
generate, based on the applying, a predictive model for estimating occupancy among the plurality of workspaces in the open environment, wherein the estimating is based on triggered sensor patterns;
determine, based on signals from one or more of the presence sensors in the open environment, a given triggered sensor pattern;
apply the given triggered sensor pattern across the predictive model to estimate occupancy among the plurality of workspaces in the environment; and
use the estimated occupancy among the plurality of workspaces to manage energy usage in the environment.

10. The system of claim 9, wherein the predictive model comprises a regression model.

11. The system of claim 10, wherein the regression model is an exponential regression model.

12. The system of claim 9, wherein applying the plurality of simulated occupancy patterns comprises performing a Monte Carlo simulation.

13. The system of claim 12, wherein a feature extracted during the Monte Carlo simulation is a number of presence sensors triggered given a particular simulated occupancy pattern.

14. The system of claim 9, wherein each workspace comprises a desk.

15. At least one non-transitory computer-readable medium comprising instructions that, in response to execution of the instructions by one or more processors, cause the one or more processors to perform the following operations:
identifying a spatial distribution of a plurality of workspaces in an open environment;
identifying spatial distribution of a plurality of presence sensors in the open environment;
generating a surrogate model based on the spatial distribution of workspaces and the spatial distribution of presence sensors, wherein the surrogate model indicates which workspaces in the open environment are within sensor range of each presence sensor in the open environment;
applying a plurality of simulated occupancy patterns across the surrogate model to generate a corresponding plurality of triggered sensor patterns, wherein each simulated occupancy pattern simulates a particular occupancy among the plurality of workspaces in the open environment;
generating, based on the applying, a predictive model for estimating occupancy among the plurality of workspaces in the open environment, wherein the estimating is based on triggered sensor patterns;
determining based on signals from one or more of the presence sensors in the open environment, a given triggered sensor pattern;
applying the given triggered sensor pattern across the predictive model to estimate occupancy among the plurality of workspaces in the environment; and
using the estimated occupancy among the plurality of workspaces to manage energy usage in the environment.
